(19) United States
(12) Patent Application Publication
(10) Pub. No.: US 2020/0099110 A1
(43) Pub. Date: Mar. 26, 2020

(54) Method of Managing Batteries and Power Supply System

(71) Applicant: ACER INCORPORATED, New Taipei City (TW)

(72) Inventor: Jiunn-Jou Lin, New Taipei City (TW)

(21) Appl. No.: 16/276,630

(22) Filed: Feb. 15, 2019

(30) Foreign Application Priority Data
Sep. 26, 2018 (TW) 107133801

(51) Int. Cl. H01M 10/44; H01M 10/48; H01M 10/42; G01R 19/165; H02J 7/00

(52) U.S. Cl. CPC H01M 10/441; H01M 10/482; H01M 10/425; H01M 2010/4278; H02J 7/0016; H02J 7/0019; H01M 2010/4271; G01R 19/16542

(57) ABSTRACT

A method of managing batteries for a power supply system is provided. The power supply system includes a plurality of battery units which are connected in series to form a battery path. The method of managing batteries includes sensing a battery voltage of each battery unit of the power system, and for each battery unit, controlling a switching unit corresponding to the each battery unit according to the battery voltage of the each battery unit, such that the battery unit is selectively serially connected to the battery path or bypasses the battery path.

### BACKGROUND OF THE INVENTION

### 1. Field of the Invention

The present invention relates to a method of managing batteries and power supply system, and more particularly, to a method of managing batteries and power supply system capable of dynamically managing battery units in power supply system.

### 2. Description of the Prior Art

In general, a power supply system may integrate multiple battery units for storing and providing power in order to increase the power capacity. When the power supply system performs a charging operation or a discharging operation, each battery unit may have different charging and discharging capabilities due to non-ideal factors, such as process variations and coupling relationships. The power supply system usually uses battery balancing technology to balance the stored energy in the battery units during the charging operation and the discharging operation. As such, the battery balancing technology has become necessary for the power supply system for protecting battery units and extending the life of the power supply system.

The battery balancing techniques can be broadly categorized into passive and active balancing. In the passive balancing method, the battery unit with higher power can be discharged through switching of passive components until the stored energy of the battery unit closely matches other battery units, and the battery unit performs the charging operation. The passive balancing method is low cost, but the passive balancing method may cause additional thermal energy and extra power consumption during charging operation. In the active balancing method, the battery unit with higher power charges the other battery unit to balance power energy between battery units. Although the active balancing method does not generate additional thermal energy and require extra power consumption, the active balancing method needs to add a determination circuit to control the power of each battery unit, thus increasing the system complexity and manufacturing costs.

Therefore, how to solve the above mentioned problems has become an important issue in the field.

### SUMMARY OF THE INVENTION

Based on the aforementioned disadvantages of the prior art, it is therefore a primary objective of the present invention to provide a method of managing batteries and power supply system capable of dynamically managing battery units in power supply system so as to extend the life of the power supply system, secure user safety and improve overall power usage efficiency of the power supply system.

The present invention discloses a battery managing method for a power supply system, the power supply system comprising a plurality of battery units connected in series to form a battery path, the battery managing method comprising: sensing a battery voltage of each battery unit of the power supply system; and for each battery unit, controlling a switching unit corresponding to the each battery unit according to the battery voltage of the each battery unit, such that the each battery unit is selectively serially connected to or bypasses the battery path.

The present invention further discloses a power supply system, comprising: a plurality of battery units for storing power; a plurality of switching units corresponding to the plurality of battery units respectively, wherein each switching unit is configured to switch a corresponding battery unit to be selectively serially connected to the battery path or bypasses the battery path; and a processing circuit for sensing a battery voltage of each battery unit and controlling the corresponding switching unit of the each switching unit; wherein for each battery unit, the processing circuit controls the corresponding switching unit of the each battery unit according to the battery voltage of the each battery unit, such that the each battery unit is selectively serially connected to or bypasses the battery path.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a power supply system according to an embodiment of the present invention.

FIG. 2A and FIG. 2B are schematic diagrams illustrating operations of a battery unit and a corresponding switching unit of the power supply system according to embodiments of the present invention.

FIGS. 3A-3D are schematic diagrams illustrating the coupling relationships of the power supply system during the charging operation according to embodiments of the present invention.

FIG. 4 is a schematic diagram illustrating a voltage between output terminals during the charging operation according to an embodiment of the present invention.

FIG. 5 is a schematic diagram illustrating a voltage between output terminals during the discharging operation according to an embodiment of the present invention.

FIG. 6 is a schematic diagram of the switching unit shown in FIG. 1 according to an embodiment of the present invention.

FIG. 7 is a schematic diagram of a procedure according to an embodiment of the present invention.

### DETAILED DESCRIPTION

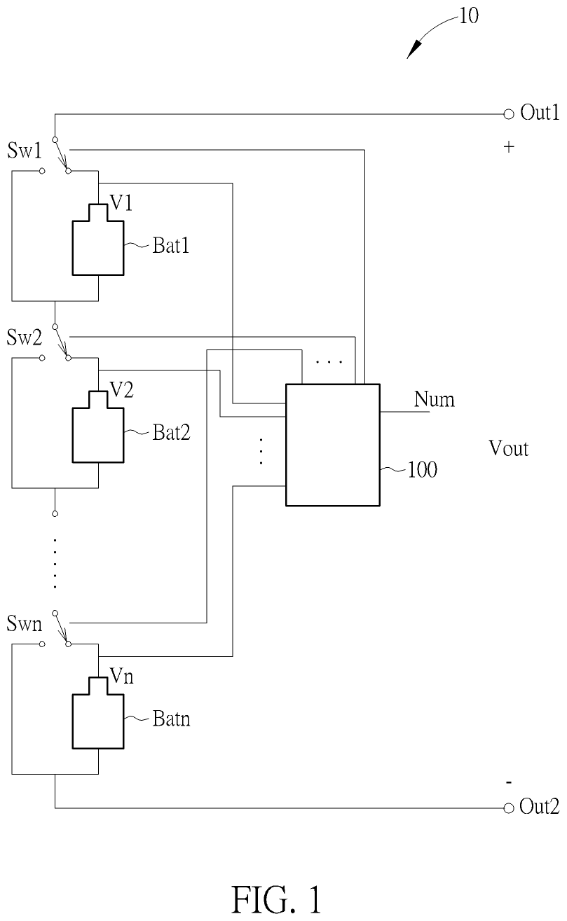

Please refer to FIG. 1, which is a schematic diagram of a power supply system 10 according to an embodiment of the present invention. The power supply system 10 can repeatedly perform charging and discharging operations. The power supply system 10 can obtain power from an external power source through output terminals Out1 and Out2 and store power. Moreover, the power supply system 10 can provide the stored power to an electronic device for operation. The power supply system 10 includes battery units Bat1-Batn. Each battery unit can be used separately to store or provide power. The power supply system 10 integrates multiple internal battery units through a series connection manner to form a power storage system which can store power and supply current. Each battery unit may have different charging and discharging characteristics and aging rates for charging and discharging due to process variation, battery unit setting or different usage conditions. Since each battery unit has different aging rates for charging and discharging, each battery units of the power supply system 10 has different degrees of aging. When the battery units with different degrees of aging are charging, the aging battery unit may be fully charged and the remaining battery units which are not fully charged still need to be charged. On the other hand, when the battery units with different degrees of aging are discharging, the aged battery unit may be exhausted and the remaining battery units which have sufficient energy still need to be discharged. Under such a condition, since the power supply system has aging or degraded battery units, there is a safety hazard for the user using the power supply system during charging and discharging. Therefore, the present invention provides a power supply system 10 to improving the safety hazard to the user when the power supply system 10 having the aged battery unit performs charging and discharging, and improving the safety of the power supply system 10.

In more detail, the power supply system 10 includes battery units Bat1-Batn, a system switch Sw, switching units Sw1-Swn and a processing circuit 100. Each switching unit of the power supply system 10 corresponds to a battery unit and is configured to control coupling relationship of the corresponding battery unit. The processing circuit 100 is coupled to the battery units Bat1-Batn and the switching units Sw1-Swn for sensing battery voltages V1-Vn of the battery units Bat1-Batn and accordingly indicating each switching unit to control the coupling relationship of the corresponding switching unit. In addition, the processing circuit 100 further senses a voltage Vout and accordingly controls operations of the system switch Sw.

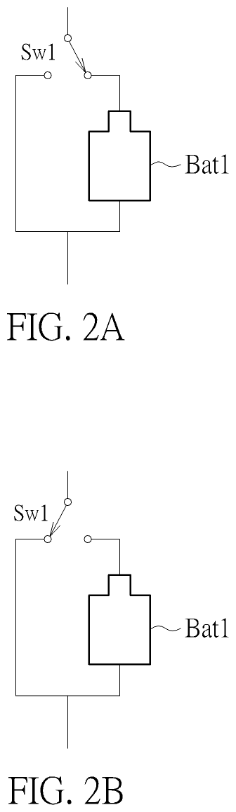

Moreover, please refer to FIG. 2A and FIG. 2B. FIG. 2A and FIG. 2B are schematic diagrams illustrating operations of the battery unit Bat1 and the switching unit Sw1 of the power supply system 10 according to embodiments of the present invention. The switching unit Sw1 determines whether to connect to the battery unit Bat1 according a control signal Ctrl1 generated by the processing circuit 100. As shown in FIG. 2A, when the switching unit Sw1 is connected to the battery unit Bat1, the battery unit Bat1 is serially connected to the battery path and the current of the power supply system 10 passes through the battery unit Bat1. In such a situation, the battery unit Bat1 performs the same charging operation or discharging operation as the power supply system 10. As shown in FIG. 2B, when the switching unit Sw1 is not connected to the battery unit Bat1, but is directly connected to the switching unit Sw2 or the battery unit Bat2 of the next stage, such that the battery unit Bat1 bypasses the battery path and the current of the power supply system 10 does not pass through the battery unit Bat1. In other words, through the switching operation of the switching unit Sw1, the battery unit Bat1 is selectively serially connected to or bypasses the battery path of the power supply system 10. Through the switching operation of the switching unit Sw1, the battery unit Bat1 is controlled to perform the charging operation or the discharging operation. Similarly, each battery unit can be selectively serially connected to or bypasses the battery path of the power supply system 10 through the switching operation of the corresponding switching unit.

Further description associated with the charging operation of the power supply system 10 is provided as follows. First, the processing circuit 100 senses the battery voltage of each battery unit of the power supply system 10 and compares the battery voltage of the each battery unit with an overcharge voltage to determine whether the each battery is full charged. When the battery voltage of the each battery unit is smaller than the overcharge voltage, this means that the each battery unit is not full charged and the each battery unit will continue to be charged. Accordingly, the processing circuit 100 indicates the switching unit corresponding to the each battery unit (e.g., the switching unit Sw1 corresponding to the battery unit Bat1, the switching unit Sw2 corresponding to the battery unit Bat2, and such like), so that the switching unit corresponding to the each battery unit is connected to the each battery unit and the power supply system 10 continues to charge the each battery unit that is not full charged. When the battery voltage of the each battery unit is greater than or equal to the overcharge voltage, this means that the each battery unit has been full charged. Accordingly, the processing circuit 100 indicates the switching unit corresponding to the each battery unit to bypass the each battery unit, so that the power supply system 10 stops charging the each battery unit that is full charged and the power supply system 10 continues to charge other battery units.

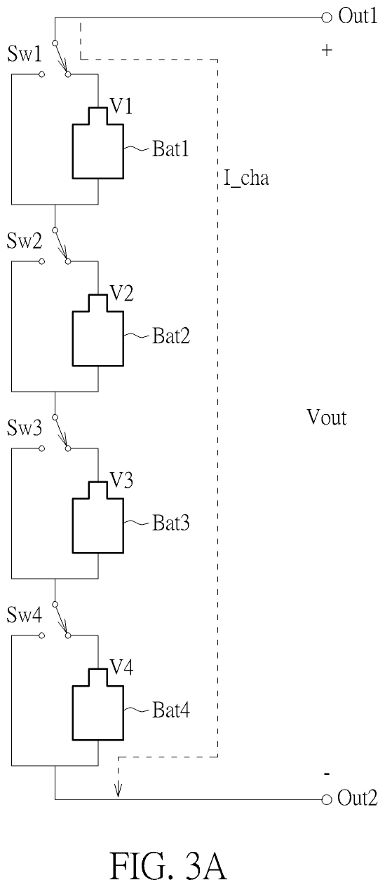

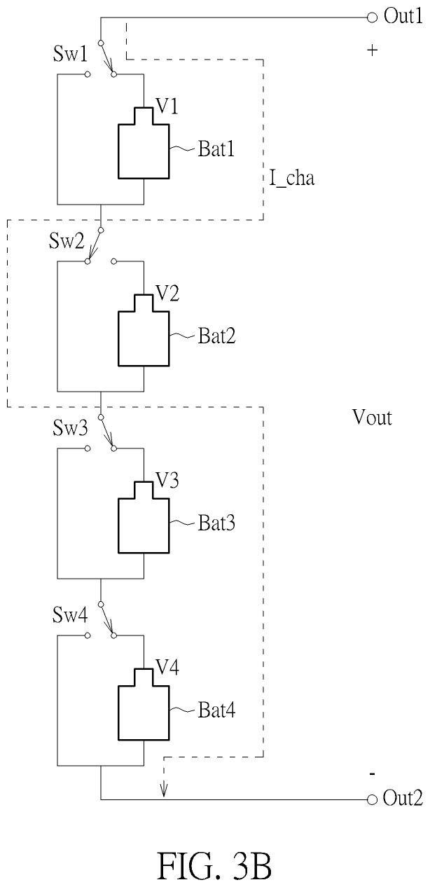

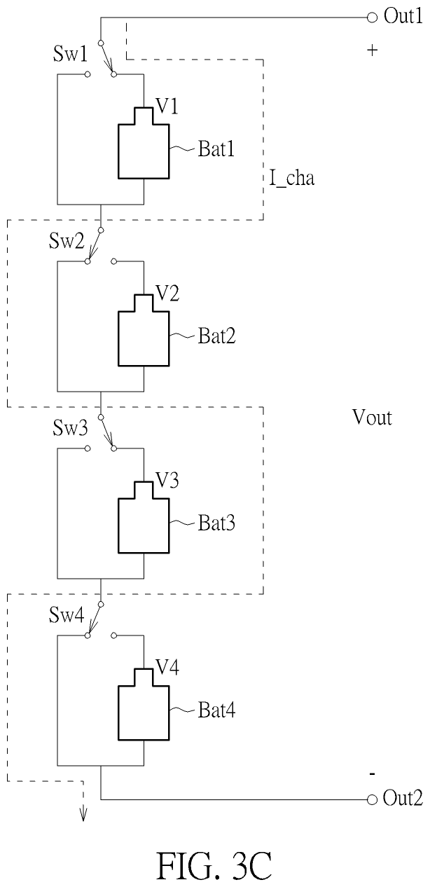

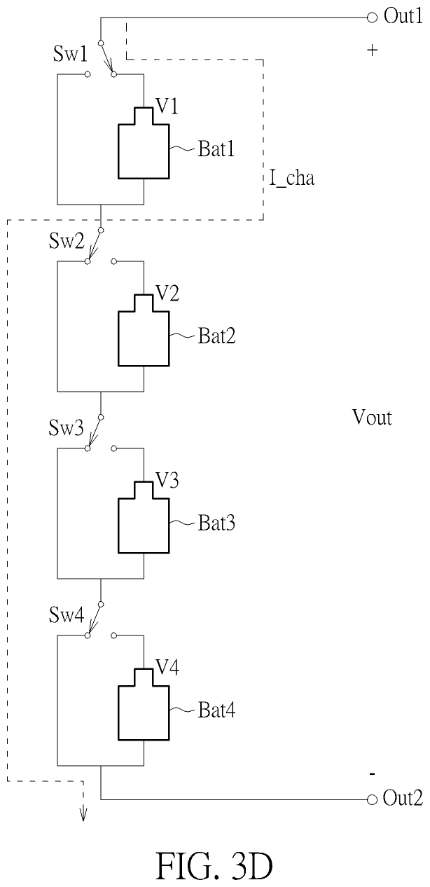

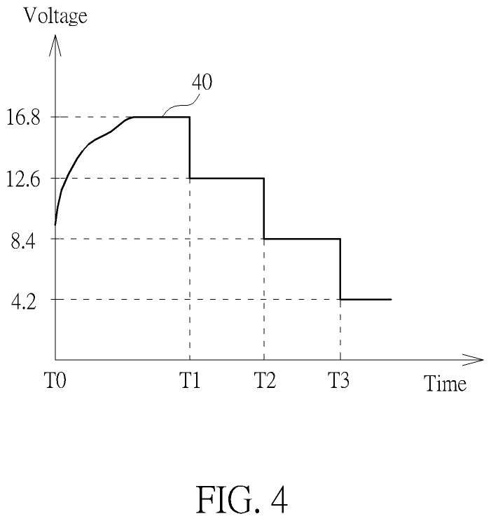

Taking four battery units and four switching units for example, please refer to FIGS. 3A-3D and FIG. 4. FIGS. 3A-3D are schematic diagrams illustrating the coupling relationships of the power supply system 10 during the charging operation according to embodiments of the present invention. FIG.4 is a schematic diagram illustrating a voltage Vout between output terminals Out1 and Out2 during the charging operation according to an embodiment of the present invention. In this embodiment, the power supply system 10 includes battery units Bat1-Bat4 and switching units Sw1-Sw4, and the overcharge voltage of the battery units Bat1-Bat4 is set to 4.2 volts. FIGS. 3A-3D show the continue time operations of the power supply system 10. The coupling relationship of the power supply system 10 shown in FIG. 3A corresponds to the time period between T0 and T1 shown in FIG. 4. The coupling relationship of the power supply system 10 shown in FIG. 3B corresponds to the time period between T1 and T2 shown in FIG. 4. The coupling relationship of the power supply system 10 shown in FIG. 3C corresponds to the time period between T2 and T3 shown in FIG. 4. The coupling relationship of the power supply system 10 shown in FIG. 3D corresponds to the time period after T3 shown in FIG. 4. Note that, the processing circuit 100 is not shown in FIGS. 3A-3D here for brevity.

When an external power source provides power to the power supply system 10 through the output terminals Out1 and Out2, the power supply system 10 begins performing the charging operation. The processing circuit 100 senses and obtains battery voltages V1-V4 of the battery units Bat1-Bat4 and determines whether the battery voltages V1-V4 are smaller than the overcharge voltage. As shown in FIG. 3A, the processing circuit 100 compares each of battery voltage V1-V4 with the overcharge voltage and determines that all of the battery voltages V1-V4 do not reach the overcharge voltage (i.e. V1, V2, V3, V4<overcharge voltage (4.2 volts)). Therefore, the processing circuit 100 controls the switching units Sw1-Sw4 to be connected to the battery units Bat1-Bat4, respectively. As a result, through controlling the switching units Sw1-Sw4, the battery units Bat1-Bat4 are serially connected to form a battery path, such that the charging current I_cha of the power supply system 10 can pass through the battery path formed by the battery units Bat1-Bat4 and charge the battery units Bat1-Bat4. Further, as shown in FIG. 3B, when the processing circuit 100 determines that the battery voltage V2 is greater than or equal to the overcharge voltage (i.e. V2≥overcharge voltage=4.2 volts), the processing circuit 100 controls the switching unit Sw2 bypasses the battery unit Bat2. As shown in FIG. 3B, one terminal of the switching unit Sw2 is coupled to the battery unit Bat1 and the other terminal of the switching unit Sw2 is coupled to the battery unit Bat3 controlled by the processing circuit 100. Moreover, since the battery voltages V1, V3 and V4 are smaller than the overcharge voltage (i.e. V1, V3, V4<overcharge voltage (4.2 volts)), the processing circuit 100 controls the switching units Sw1, Sw3, Sw4 to be connected to the battery unit Bat1, Bat3, Bat4, respectively. As a result, the battery units Bat1, Bat3 and Bat4 are serially connected to form a battery path, such that the charging current I_cha of the power supply system 10 can pass through the battery path formed by the battery units Bat1, Bat3 and Bat4. Under such a situation, the power supply system 10 bypasses the battery unit Bat2 which is fully charged and excludes the battery unit Bat2 from the charging operation. The battery units Bat1, Bat3 and Bat4 which are not fully charged can be remained on the battery path and charging current I_cha of the power supply system 10 continues to charge the battery units Bat1, Bat3 and Bat4. Moreover, as shown in FIG. 3C, when the processing circuit 100 determines that the battery voltage V4 is greater than or equal to the overcharge voltage, the processing circuit 100 further indicates the switching unit Sw4 to bypass the battery unit Bat4, such that the charging current I_cha of the power supply system 10 does not pass through and charge the battery unit Bat4. As shown in FIGS. 3D, when the processing circuit 100 determines that the battery voltage V3 is greater than or equal to the overcharge voltage, the processing circuit 100 further indicates the switching unit Sw3 to bypass the battery unit Bat3, such that the charging current I_cha of the power supply system 10 does not pass through and charge the battery unit Bat3.

As shown in FIG. 4, a curve 40 shows the voltage Vout between the output terminal Out1 and the output terminal Out2. During the time period T0-T1, the processing circuit 100 determines that the battery voltages V1-V4 of the battery unit Bat1-Bat4 do not reach the overcharge voltage. Therefore, the voltage Vout between the output terminal Out1 and the output terminal Out2 gradually increases since the external power source charges the power supply system with the constant current (CC) mode. At time T1, the processing circuit 100 determines that the battery voltage V2 of the battery unit Bat2 has reached the overcharge voltage and accordingly controls the switching unit Sw2 to bypass the battery unit Bat2, such that the battery unit Bat2 is excluded from the battery path and does not perform the charging operation. Note that, the processing circuit 100 further generates a battery unit number signal Num and transmits the battery unit number signal Num to the external power source. The battery unit number signal Num represents the number of the battery units which are performing the charging operation in the power supply system 10, such that the external power source adjusts the voltage Vout according to the battery unit number signal Num. For example, at time T1, the processing circuit 100 determines that the battery voltage V2 is greater than the overcharge voltage and the battery unit Bat2 is switched into the bypass path. Under such a condition, the battery unit number signal Num indicates the number of the battery units which are performing the charging operation is three. The voltage Vout can be adjusted to a product of the number of battery unit indicated by the battery unit number signal Num and the overcharge voltage (3*4.2 volts 12.6 volts). As such, the external power supply reduces the voltage Vout (i.e. the voltage Vout falls from 16.8 volts to 12.6 volts) according to the indication of the processing circuit 100, so as to adaptively adjust the charging operation for the power supply system 10. Similarly, at time T2, the processing circuit 100 determines that the battery voltage V4 is greater than the overcharge voltage and controls the battery unit Bat4 to be switched into the bypass path, such that the battery unit Bat4 is excluded from the battery path and does not perform the charging operation. Accordingly, the external power supply further reduces the voltage Vout (i.e. the voltage Vout falls from 12.6 volts to 8.4 volts) according to the indication of the processing circuit 100. Similarly, at time T3, the processing circuit 100 determines that the battery voltages V3 is greater than the overcharge voltage and controls the battery unit Bat3 to be switched into the bypass path, such that the battery unit Bat3 is excluded from the battery path and does not perform the charging operation. Accordingly, the external power supply further reduces the voltage Vout (i.e. the voltage Vout falls from 8.4 volts to 4.2 volts).

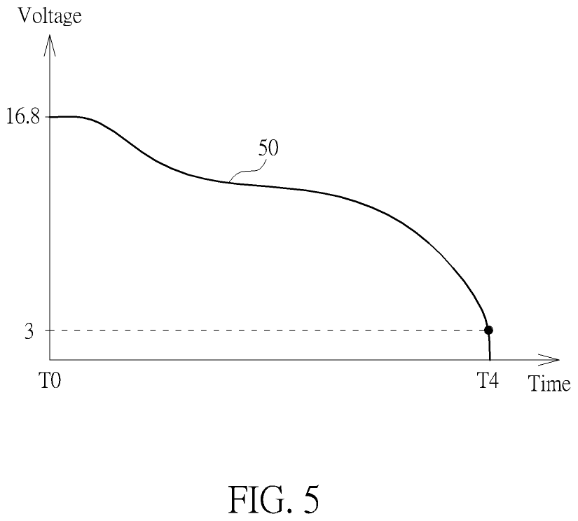

Further, please refer to FIG. 5. FIG.5 is a schematic diagram illustrating a voltage Vout between output terminals Out1 and Out2 during the discharging operation according to an embodiment of the present invention. Similarly, Taking four battery units and four switching units for example, the power supply system 10 includes battery units Bat1-Bat4 and switching units Sw1-Sw4. The over-discharge voltage of the battery units Bat1-Bat4 is set to 3 volts. As shown in FIG. 5, a curve 50 shows the voltage Vout between the output terminal Out1 and the output terminal Out2. At the beginning, the battery units Bat1-Bat4 which are fully charged can supply power for the power supply system 10. At time T0, the voltage Vout provided by the power supply system 10 is 16.8 volts (i.e. four times the overcharge voltage). With power consumption, the processing circuit 100 compares the battery voltages V1-V4 with the over-discharge voltage. When determining that the battery voltage is smaller than or equal to the over-discharge voltage, the processing circuit 100 controls the switching unit corresponding to the battery unit bypasses the battery unit, such that the battery unit is excluded from the battery path and does not perform the discharging operation. Note that, the power supply system 10 can be set to finish the discharging operation when the outputted voltage Vout is too low. For example, in this embodiment, the power supply system 10 is set to finish the discharging operation when the output voltage Vout is below 3 volts. Therefore, at time T4, the processing circuit 100 determines that the voltage Vout is smaller than 3 volts (i.e. over-discharge voltage) and controls the system switch Sw to finish the discharging operation of the power supply system 10. In other words, the power supply system 10 can bypass the battery unit which has been exhausted and continue to perform the discharging operation. Therefore, he power supply system 10 does not need to stop the discharge operation while any battery unit is exhausted, thus improving the power usage efficiency of the power supply system 10

To sum up, through sensing the battery voltage of the battery unit and accordingly controlling the operation of the corresponding switching unit by the processing circuit 100, the power supply system 10 bypasses the battery unit which is fully charged and continues to charge the remaining battery units which are not fully charged during charging. Moreover, the power supply system 10 bypasses the battery unit which is exhausted and continues to discharge the remaining battery units which are not exhausted during discharging. Therefore, for the battery units with different charging and discharging characteristics and different degrees of aging, the power supply system 10 can adjust the charging and discharging time of each battery unit so as to extend the life of the power supply system 10, secure user safety and improve overall power usage efficiency of the power supply system 10.

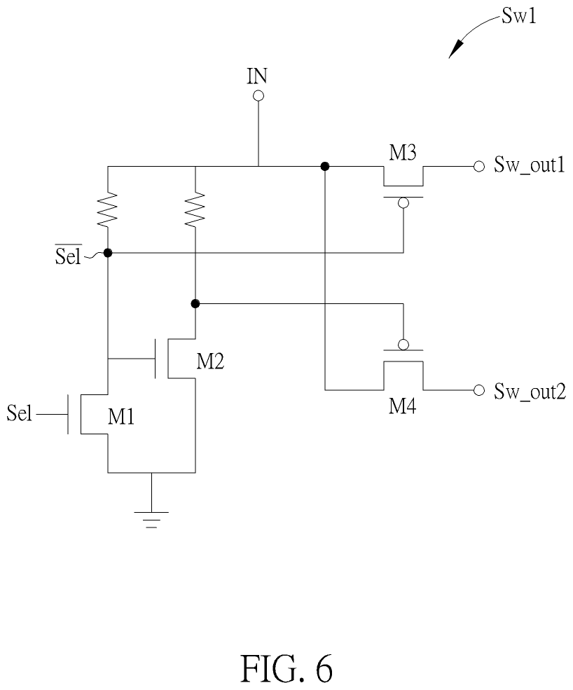

The following further illustrates operations of the switching unit. In an embodiment, taking the switching unit Sw1 for example, please refer to FIG. 1 and FIG. 6. FIG. 6 is a schematic diagram of the switching unit Sw1 shown in FIG. 1 according to an embodiment of the present invention. An input terminal IN of the switching unit Sw1 is coupled to the output terminal Out1, an output terminal Sw_out1 of the switching unit Sw1 is coupled to the battery unit Bat2 and an output terminal Sw_out2 of the switching unit Sw1 is coupled to the battery unit Bat1. The switching unit Sw1 selectively connects the input terminal IN to the output terminal Sw_out1 or the output terminal Sw_out2 according to a selection signal Sel. In more detail, the switch Sw1 can be a single pole double throw (SPDT) switch. The switch Sw1 includes N-type metal oxide semiconductor (NMOS) transistors M1 and M2, P-type metal oxide semiconductor (PMOS) transistors M3 and M4. The NMOS transistor Ml is utilized for receiving the selection signal S̅e̅l̅ and accordingly indicating whether the PMOS transistors M3 connects the input terminal IN to the output terminal Sw_out1. The NMOS transistor M2 is utilized for receiving an inverted selection signal Sel and accordingly indicating whether the PMOS transistors M4 connects the input terminal IN to the output terminal Sw_out2. Note that, according to various applications and design concepts, the switching unit Sw1 can be implemented by using any implementation method or circuit which can selectively connect the input terminal IN to the output terminal Sw_out1 or the output terminal Sw_out2.

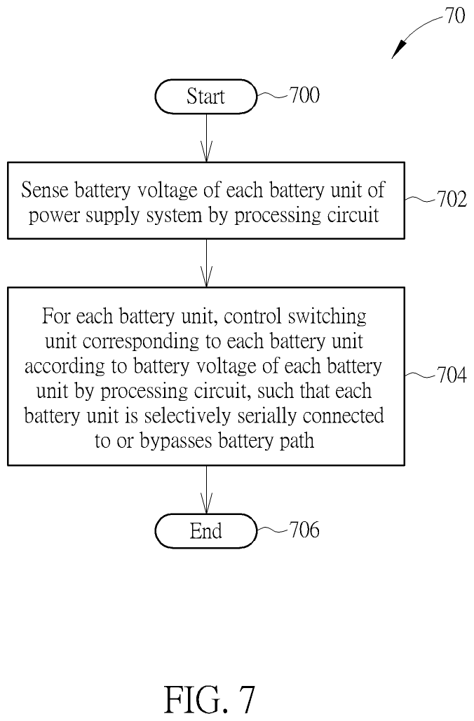

For an illustration of the operations of the power supply system 10, please refer to FIG. 7. FIG. 7 is a schematic diagram of a procedure 70 according to an exemplary embodiment of the invention. The procedure 70 includes the following steps:

Step 700: Start.

Step 702: Sense battery voltage of each battery unit of power supply system 10 by processing circuit 100.

Step 704: For each battery unit, control switching unit corresponding to each battery unit according to battery voltage of each battery unit by processing circuit 100, such that each battery unit is selectively serially connected to or bypasses battery path.

Step 706: End.

The operation method of the procedure 70 has been illustrated above, so the detailed description is omitted herein.

During the charging operation or the discharging operation, the conventional power supply system can only be individually turned on or turned off to simultaneously charge or discharge all internal battery units. As such, the conventional power supply system cannot exclude the fully charged battery unit during the charging operation and does continuously charge the fully charged battery during charging, resulting in user safety hazard. Besides, the depleted battery unit would cause the conventional power supply system to be turned off during the discharging operation, such that the power stored in the remaining battery units which are not exhausted cannot be effectively used. In comparison, the power supply system of the present invention senses the battery voltage of each battery unit and respectively controls the switching unit corresponding to each battery unit according to the battery voltage, so as to dynamically adjust the battery path in the power supply system. Through the control operations of the power supply system, the power supply system of the present invention is able to avoid continuously charging the fully charged battery unit during the charging operation and to avoid continuously discharging the exhausted battery unit during the discharging operation. Therefore, the power supply system of the present invention can dynamically adjust the battery path, thus extending the life of the power supply system, securing user safety and improving overall power usage efficiency of the power supply system.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of managing batteries for a power supply system, the power supply system comprising a plurality of battery units connected in series to form a battery path, the method comprising:
sensing a battery voltage of each battery unit of the power supply system; and
for each battery unit, controlling a switching unit corresponding to the each battery unit according to the battery voltage of the each battery unit, such that the each battery unit is selectively serially connected to or bypasses the battery path.

2. The method of claim 1 wherein the step of controlling the switching unit corresponding to the each battery unit according to the battery voltage of the battery unit, such that the each battery unit is selectively serially connected to or bypasses the battery path comprises:
when the power supply system performs a discharging operation, comparing the battery voltage of the each battery unit with a first voltage;
when the battery voltage of the each battery unit is smaller than or equal to the first voltage, determining not to couple the switching unit to the each battery unit, such that the each battery unit bypasses the battery path and the each battery unit does not perform the discharging operation; and
when the battery voltage of the each battery unit is greater than the first voltage, determining to couple the switching unit to the each battery unit, such that the each battery unit is serially connected to the battery path and performs the discharging operation.

3. The method of claim 1, wherein the step of for each battery unit, controlling the switching unit corresponding to the each battery unit according to the battery voltage of the battery unit, such that the each battery unit is selectively serially connected to or bypasses the battery path comprises:
when the power supply system performs a charging operation, comparing the battery voltage of the each battery unit with a second voltage;
when the battery voltage of the each battery unit is greater than or equal to the second voltage, determining not to couple the switching unit to the each battery unit, such that the each battery unit bypasses the battery path and the each battery unit does not perform the charging operation; and
when the battery voltage of the each battery unit is smaller than the second voltage, determining to couple the switching unit to the each battery unit, such that the each battery unit is serially connected to the battery path and performs the charging operation.

4. The method of claim 3, further comprising:
generating a battery unit number signal according to the number of battery units included in the battery path of the power supply system;
wherein a charging voltage is adjusted according to the battery unit number signal during the charging operation and the charging voltage is equal to a product of the number of battery units included in the battery path of the power supply system and the second voltage.

5. A power supply system, comprising:
a plurality of battery units for storing power;
a plurality of switching units corresponding to the plurality of battery units respectively, wherein each switching unit is configured to switch a corresponding battery unit to be selectively serially connected to the battery path or bypass the battery path; and
a processing circuit for sensing a battery voltage of each battery unit and controlling the corresponding switching unit of the each switching unit;
wherein for each battery unit, the processing circuit controls the corresponding switching unit of the each battery unit according to the battery voltage of the each battery unit, such that the each battery unit is selectively serially connected to or bypasses the battery path.

6. The power supply system of claim 5 wherein when the power supply system performs a discharging operation, the processing circuit compares the battery voltage of the each battery unit with a first voltage, the processing circuit determines not to couple the switching unit to the each battery unit such that the each battery unit bypasses the battery path and does not perform the discharging operation when the battery voltage of the each battery unit is smaller than or equal to the first voltage, and the processing circuit determines to couple the switching unit to the each battery unit such that the each battery unit is serially connected to the battery path and performs the discharging operation when the battery voltage of the each battery unit is greater than the first voltage.

7. The power supply system of claim 5 wherein when the power supply system performs a charging operation, the processing circuit compares the battery voltage of the each battery unit with a second voltage, the processing circuit determines not to couple the switching unit to the each battery unit such that the each battery unit bypasses the battery path and does not perform the charging operation when the battery voltage of the each battery unit is greater than or equal to the second voltage, and the processing circuit determines to couple the switching unit to the each battery unit such that the each battery unit is serially connected to the battery path and performs the charging operation when the battery voltage of the each battery unit is smaller than the second voltage.

8. The power supply system of claim 7 wherein the processing circuit further generates a battery unit number signal according to the number of battery units included in the battery path of the power supply system, wherein a charging voltage is adjusted according to the battery unit number signal during the charging operation and the charging voltage is equal to a product of the number of battery units included in the battery path of the power supply system and the second voltage.
